(19) United States
(12) Patent Application Publication
(10) Pub. No.: US 2011/0000528 A1
(43) Pub. Date: Jan. 6, 2011

(54) AVALANCHE BREAKDOWN PROTECTION FOR HIGH CURRENT, NON-ELONGATE SOLAR CELLS WITH ELECTRICALLY CONDUCTIVE SUBSTRATES

(76) Inventors: Anthony Nicholas Brady Garvan, III, San Jose, CA (US); Robert Stancel, Los Altos, CA (US)

Correspondence Address: Director of IP, 5521 Hellyer Avenue, San Jose, CA, 95138, US

(21) Appl. No.: 12/769,642

(22) Filed: Apr. 28, 2010

Related U.S. Application Data
(60) Provisional application No. 61/173,570, filed on Apr. 28, 2009.

(51) Int. Cl. H01L 31/107

(52) U.S. Cl. 136/252; 257/E31.063

(57) ABSTRACT

Methods and devices are provided for avalanche breakdown in a thin-film solar cell.

### CROSS REFERENCE TO RELATED APPLICATIONS

This application claims priority to U.S. Provisional Application Ser. No. 61173,570 filed Apr. 28, 2009, fully incorporated herein by reference for all purposes.

### FIELD OF THE INVENTION

This invention relates to using thin-film photovoltaic absorber material on a photovoltaic device to provide breakdown protection.

### BACKGROUND OF THE INVENTION

A central challenge in cost-effectively providing breakdown protection in a photovoltaic device relates in part to the materials used for the photovoltaic cells and the high cost associated with traditional devices packaged for use in the solar industry. Furthermore, thin-film solar cells such as those comprised of CIGS or other IB-IIIA-VIA material have often not needed diodes as these cells when made on metal foil, were able to withstand hot spots without comprising the entire module. However, many issues remain that may be addressed by having breakdown protection.

Thus, there is a need for an improved photovoltaic breakdown protection device.

### SUMMARY OF THE INVENTION

The disadvantages associated with the prior art are overcome by embodiments of the present invention.

In one embodiment of the present invention, a non-elongated, non-silicon thin-film solar cell is provided using an electrically conductive foil substrate wherein the foil substrate carries current when the cell is forward biased, the substrate having a ratio of width to length greater than about 0.5 along an axis of current flow, and when exposed to light at AM 1.5 G, the solar cell has an Impp greater than about 2 amps; wherein the solar cell exhibits avalanche breakdown down at one or more locations in the cell; and an avalanche breakdown protection unit to prevent the avalanche breakdown at the one or more locations by directing current through the protection unit. In one embodiment, the foil substrate can be aluminum, aluminum with an anodized layer, stainless steel, carbon steel, copper, combinations of the foregoing, cladded foils using one or more the foregoing, or other electrically conductive metal foils. In one embodiment, the conductive substrate creates the avalanche breakdown due to the much larger current that can be delivered to any one location in the cell.

In one embodiment, the % IACS units for the conductive metal substrate is in the range of about 30 to 62. Optionally, the resistivity of the conductive metal substrate is 2.65×10⁻⁸ Ω·m to 3×10⁻⁸ Ω·m.

A further understanding of the nature and advantages of the invention will become apparent by reference to the remaining portions of the specification and drawings.

### BRIEF DESCRIPTION OF THE DRAWINGS

FIGS. 1a-1d show various cross-sectional views of modules with breakdown protection according to embodiments of the present invention.

FIGS. 2-11 show various embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for a barrier film, this means that the barrier film feature may or may not be present, and, thus, the description includes both structures wherein a device possesses the barrier film feature and structures wherein the barrier film feature is not present.

In one embodiment, a group IB-IIIA-VIA or other material maybe used as the voltage breakdown protection device. This device maybe used with a photovoltaic material made of the same material (in the same or different molar percentages). Optionally, thin-film material may be used as breakdown protection for silicon or other types of photovoltaic devices.

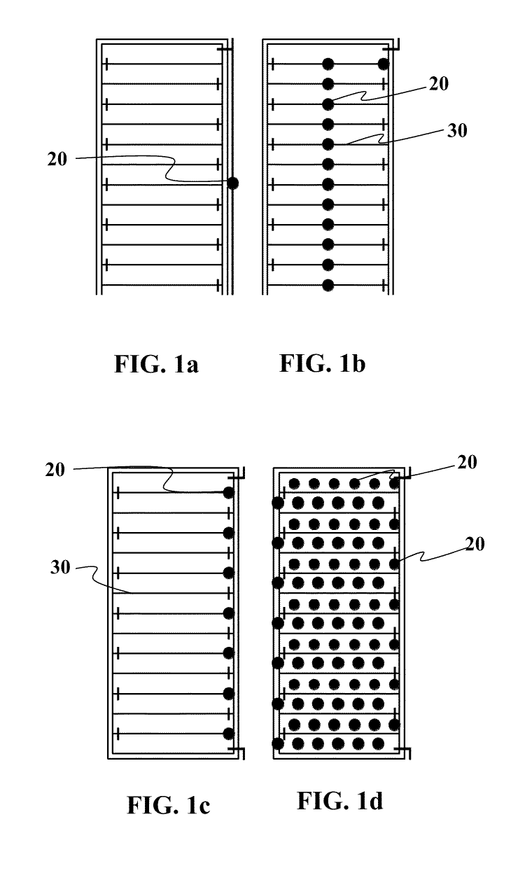

Referring now to FIGS. 1a through 1d, several configurations for use of bypass diodes in a solar module are described. FIG. 1a shows a single bypass diode 20 used as protection for an entire module with the associated threshold voltage of the bypass diode (Vbd). FIG. 1b shows at least one bypass diode 20 per string 30 of solar cells, with a separate diode at the entry and exit locations of each module. FIG. 1c shows one bypass diode per every two (2) strings of solar cells and the associated threshold voltage of the bypass diode. FIG. 1d shows that there is one diode per solar and the associated threshold voltage of the bypass diode is significantly lower.

Referring now to FIG. 2, a schematic is shown of electrical representation of a string of solar cells. When, one cell in a string is shaded, a reverse bias situation is created. As a result, the current in the entire string current is forced through the avalanche breakdown protection unit (which may be a diode) and shunt resistance. This causes reverse bias voltage=Rₛₕᵤₙₜ*I. This is not an issue while the shunt resistance was low, as most current would go through the shunts. But as shunt resistance is increasing, the voltage drop is higher.

Avalanche Breakdown: Very large E lead to Impact Ionization leads to Current; Diode or Dielectric; Positive Temperature Coefficient.

Damage can be created two ways: by heat generated through a lot of power dissipated, or by reaching the voltage breakdown.

For example: Current I is 6 A. Shunt resistance R was 50 Ohms/cm2, at 221.4 cm2 per cell that is 0.2 Ohms.

Voltage drop through cell is I×R=1.2 V.

Power dissipated is I2×R=7.2 W.

If shunt resistance goes to say 200 Ohms/cm2, voltage drop is 4.8 V, power dissipated is 32 W. This results in more power being dissipated by the cell, which can damage the cell. In a monolithically integrated cell with long, elongate cell structure, there is not the type of avalanche current breakdown that is experience with non-elongate substrates with electrically conductive substrates.

Silicon panels in general have very high shunt resistance (10 kOhms/cm2) and very high breakdown voltage (50V).

Therefore, they have bypass diodes to protect the module from destruction by heat dissipation, not to protect the cells from reaching breakdown voltage.

For the presently described cells, heat dissipation is not the issue, but a very low breakdown voltage of the cell diode.

There is also a ‘meta-stable’ CIGS effect that creates a reversible shunt resistance drop. This is discussed separately from the irreversible diode breakdown.

Cell temperatures get higher as the cell shunt resistance improves. But as far as heat dissipation goes, there is still a good margin. Reverse bias damage decreases Rsh, moderating the heat

The shading or reduced lighting issues which creates reverse bias conditions is a real world likelihood. Clouds can create irradiation differences of around 400 W/m². Objects in the sun's path can create higher differences locally.

Power loss during shading is of marginal relevance in large utility applications as these are constructed shade-free, and are being inspected and cleaned on a regular basis.

Power loss during shading will become more relevant in commercial and residential applications when a shade-free environment cannot be ensured.

What is of relevance is power loss due to irreversible cell degradation after shading, as this reduces the output of the system long-term.

Options for Improving V_{bd} on a Pixel Level

String will lose voltage contribution of cell and threshold voltage of bypass diode (0.5-0.6 V).

Caveat: bypass diodes may not activate for low Rₛₕᵤₙₜ values.

For one diode every 2 strings (12 cells), bypass diode will only activate if Rₛₕᵤₙₜ>150 Ω-cm².

If a bypass diode is located every n cells,

the maximum cell reverse bias voltage V_{RBmax} is

V_{RBmax}=(n−1)V_{oc}+Vₜ

For a diode every cell, V_{RBmax}=Vₜ≈0.6 V

For a diode every other string, V_{RBmax}=11V_{oc}+Vₜ≈5.5 V.

In reality, V_{RB} will be less than V_{RBmax}.

For one diode every two strings (12 cells), if Rₛₕᵤₙₜ>200 Ω-cm², V_{RB}>80% of V_{RBmax}.

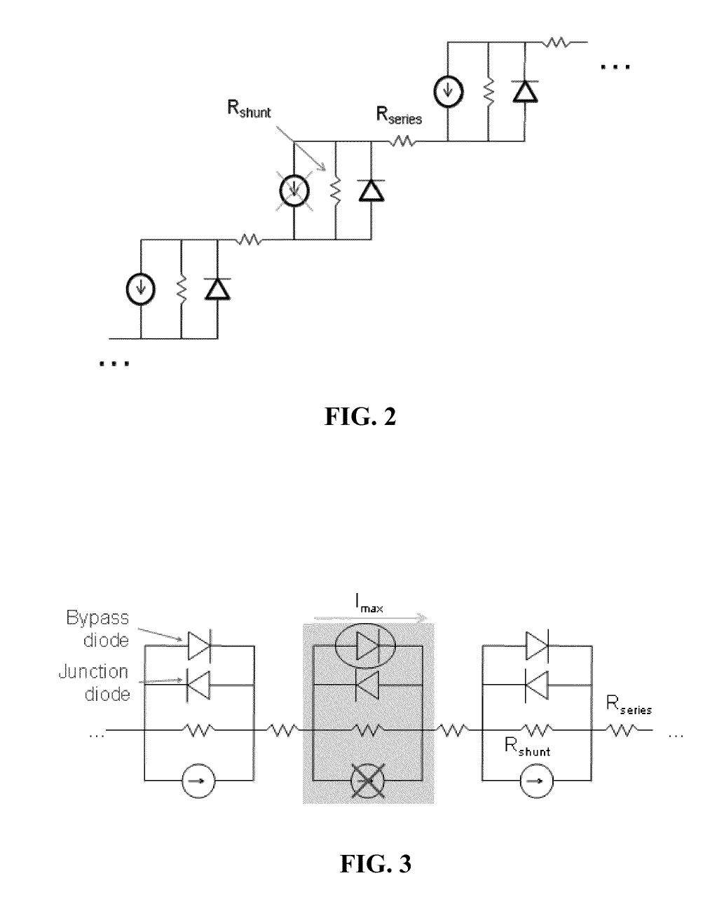

Referring now to FIG. 3, a secondary purpose is provided: the avalanche breakdown protection unit preserves string power when cells are shaded. It effectively removes shaded cell from string. This prevents shaded cell Rₛₕᵤₙₜ from being added to module series resistance.

If V_{bd} of the cells cannot be improved, every cell can be configured to include an avalanche breakdown protection unit.

Optionally, there is a possibility to deliberately create leaky solar cell diodes or to build a diode into each cell.

One option is to reduce the cell size as to reduce the current per cell.

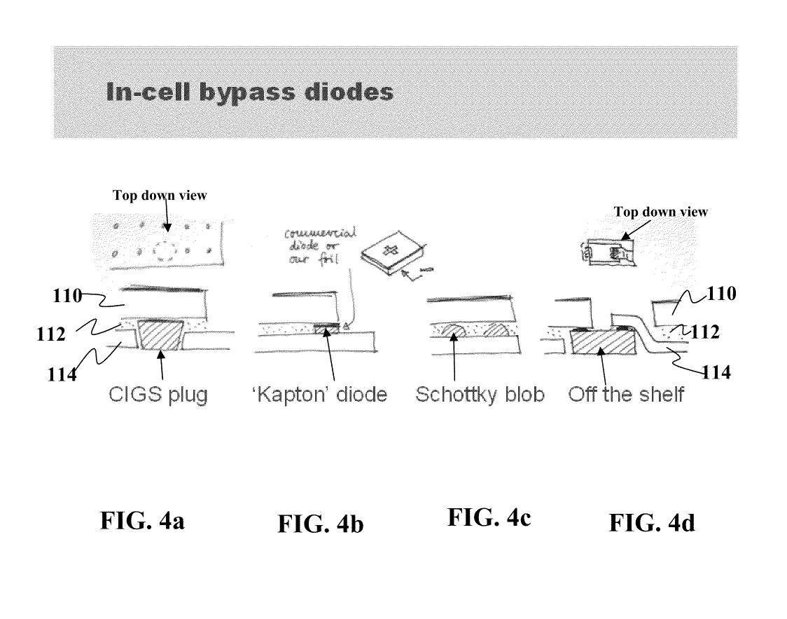

Referring to FIG. 4A, optionally, one embodiment uses a cigs plug: punch hole in 100 micron back foil and replace with 150 um front foil plug. This inverted CIGS or group IB-IIIA-VIA material used as the diode in a thin-film solar cell, with current (a)>10. This FIG. 4A shows a metal substrate 110 on which a solar cell is formed. An insulating layer 102 may optionally be used with a second metal substrate 114.

2 Optionally, one embodiment sticks diodes on strings of cells. This may involve solder, weld or conductive glue across cell welds or across strings

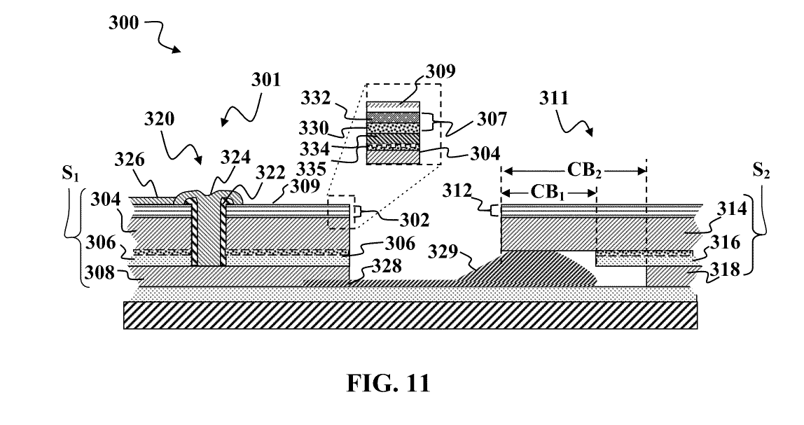

Referring to FIG. 4B, optionally, one embodiment uses schottky blob. This uses a schottky material blob over ablated tab or as primary insulator. This embodiment creates a Schottky diode between the back foil electrode and the fron foil (in parallel with the CIGS/Cds/ZnO diode), that will act as a bypass diode, which blocks current during normal operation, but allows current to pass if the solar cell becomes reverse biased during shading or reduced lighting. On way to accomplish this is to replace the primary insulator with a p-type semiconductor that form a Schottky diode with the back foil metal at the surface (such as Ag). The other side of the semiconductor (i.e. at the back of the front foil), would be contacted with an ohmic metal contact. Optionally, one could use an n-type semiconductor in place of the primary insulator, and have the Schottky barrier at the back surface of the front foil, and have an ohmic contact at the back foil. The primary insulator would not be replaced in its entirety. Rather, it could be selectively removed in areas and replaced with these schottky blobs. The cell structure of FIG. 11 can be used for the present embodiment of the schottky blobs. Some nonlimiting examples are provided below.

| | | ‘Ohmic’ Contact |
|---|---|---|
| Semiconductor (type) | Schottky Barrier Materials | Materials |
| ZnO (n-type) | Ag, Pt, Pd, Au, etc. | Ni, Al, etc. |
| TiO2 (n-type) | Ag, Cu, Pd, Au, Pt, etc. | Ag, Ti, ZnO etc. |
| CuO (p-type) | Cu, Al, Ni, Pt, ZnO:Al, etc. | Au, etc. |
| CdS (n-type) | Ag, Te, etc. | Au, ZnO:Al, etc. |

4 Optionally, one embodiment uses drop-in via

leave away one via, drop in commercial diode in that space

5 Optionally, one embodiment uses plated diode

selectively electroplate or ablate for dropping in diode dots in primary pos

6 Optionally, one embodiment uses smaller cells

well, smaller cells and the effect on reverse bias

7 Optionally, one embodiment uses ‘Kapton’ diode (as seen in FIG. 4b).

create super-thin diode from foil to go into position of Kapton tape or replace commercial diode for 1, 2, 4, 5

8 Optionally, one embodiment uses cigs back foil

plug like 1, but use whole front foil as back foil, figure out contacting

9 Optionally, one embodiment uses commercially available diode with specs: 7 A, 4 W @ 0.6V, 0.15 mm thick, 1 mA leakage current, top/bottom contact (as seen in FIG. 4d).

Optionally, one embodiment uses a cell with an area that is 20000 to 30000 mm2 per cell, with length to width aspect ratio is between 1:1 to 1:0.75.

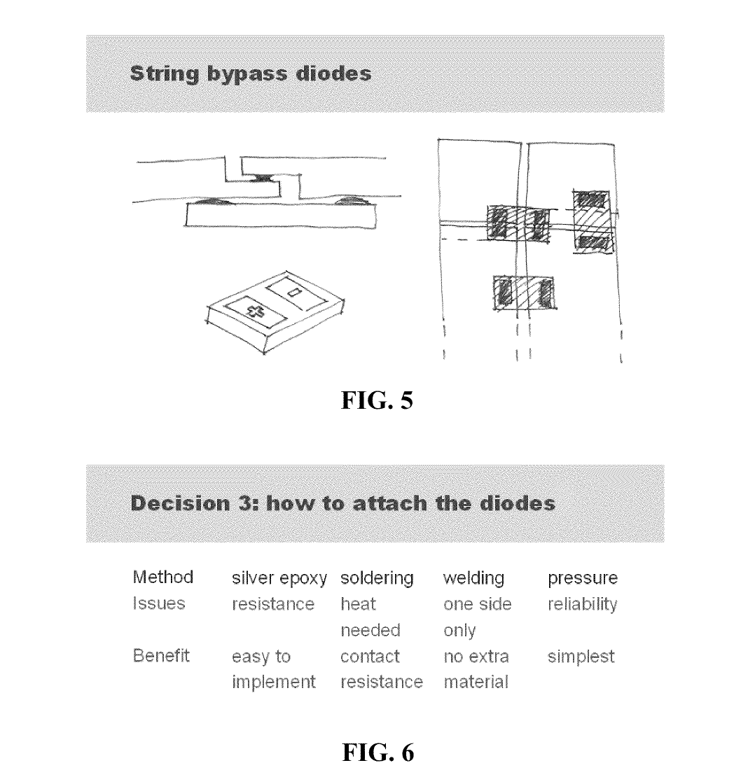

FIG. 5 shows one embodiment for a string bypass diode connection configuration.

FIG. 6 described various methods for coupling the diodes, which may be combined in single or multiple combinations. Optionally, the diode is not to be of a thickness greater than the thickness of the substrate and/or the entire cell.

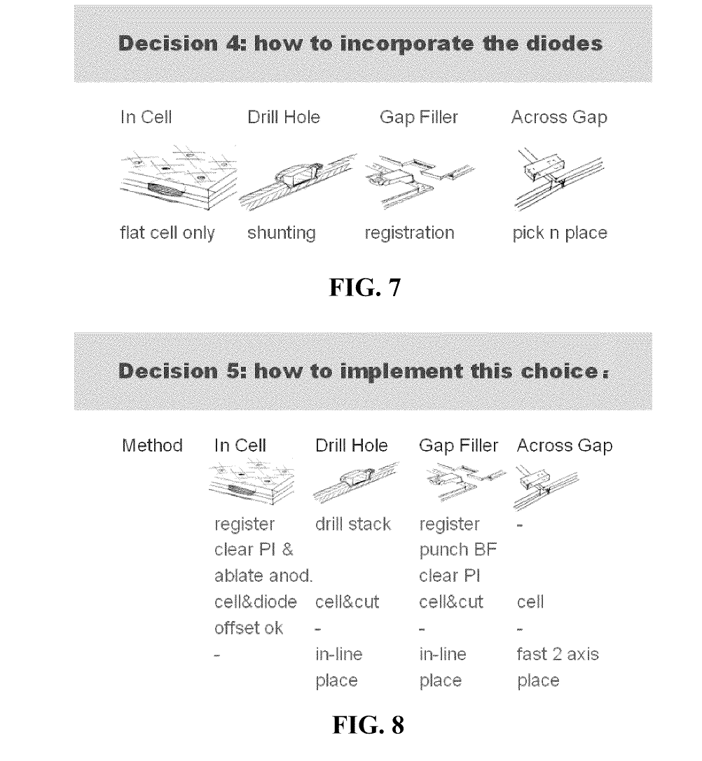

FIG. 7 shows various locations for placing the avalanche protection device on the solar cell.

FIG. 8 shows various techniques for implementing the configurations of FIG. 7.

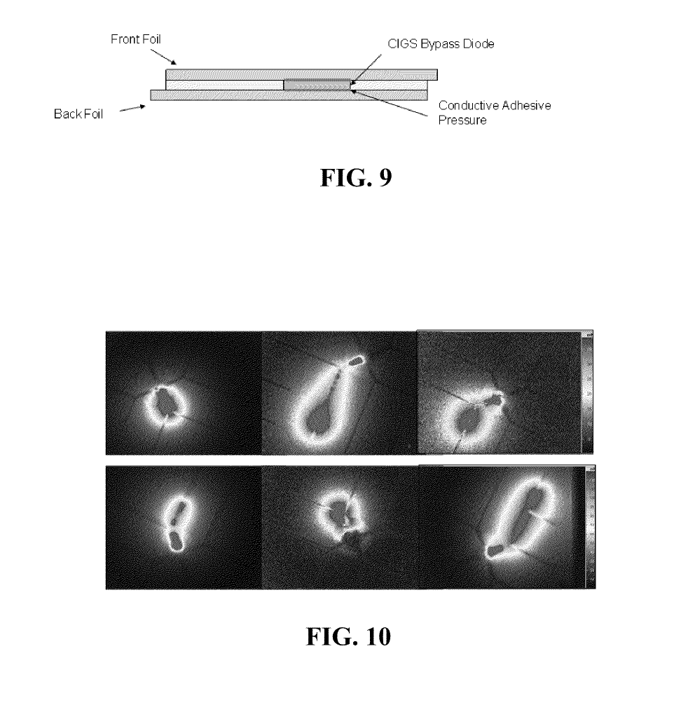

FIG. 9 shows one embodiment wherein the CIGS material is used in an inverted manner as the bypass diode.

In real world operating conditions, reverse bias situations may occur when the cell is shaded. When a CIGS solar cell is reverse biased, it may become damaged. In some CIGS solar cell, the damage may create one or more large shunts that siphon away current. The nature of a metal wrap though (MWT) structure is that the structure essentially has many small diodes in parallel, so if one creates a shunt, it can siphon current from the rest of the cell. Such siphoning could be quite severe and direct very large amounts through the shunt.

To address this issue, it should be understood that shunted areas become hotter than surrounding areas. Thus, the most severe shunts become hotter than other, less severe shunts.

FIG. 10 shows that often, the shunts created seem to be sitting under fingers. Of course, other locations are not excluded in terms of where issues that can be resolved by the present invention.

This would explain the discrepancy in breakdown voltage between pixels and EWT cells, created by pinholes through which finger ink creates shunts.

Typically, normal shunts in the absorber layer generate only very small amounts of heat. They may be created in thin film materials such as CIGS absorbers during the manufacturing process and may be randomly distributed in the absorber. Although it would be desirable to optimize manufacturing to reduce the number of these normal shunts and improve overall film quality, their existence during normal forward bias operation of the solar is generally not an issue that will completely destroy cell operation. When a solar cell is shaded and goes into reverse bias, however, new shunts may be created during such reverse bias conditions and can be so severe that they can generate sufficient energy to generate great amounts of heat. Through a single grid finger, the finger can carry several amps of current versus normal operating current of 8 to 10 milliamps. So to carry several amps in a grid finger, it is many orders of magnitude above normal power. Embodiments herein are configured so that overcurrent protection will be triggered when current carried in the finger starts a reaction that will isolate the electrical power that can be carried by that electric grid finger.

The CIGS absorber material has a reverse bias characteristic in that it can act as a diode in reverse in a safe way, but it also has a damaging reverse bias mechanism wherein if the damaging mechanism occurs before the safe method, then the whole cell becomes damage or suffers a significant decrease in conversion efficiency. The embodiments of the present invention are such that they will effectively electrically isolate the undesirable areas which develop the damaging reverse bias mechanism. Removing these areas allows the rest of the cell act as a diode in reverse in a safe way when shaded or otherwise reverse biased.

The solar cell stack may be one of any as known in the art. For a thin-film type CIGS absorber layer stack, there is typically a transparent conductive electrode layer beneath the finger. Beneath that transparent conductive electrode layer is the thin-film active layer which may comprise of CdS window layer coupled to a CIGS absorber layer. The thickness of such layers is usually in the 0.5 microns to 2.0 micron range. Below those layers may be a bottom electrode layer of material such as molybdenum. Beneath that, there may be a substrate, which in most solar cells manufactured in a roll-to-roll process, is a metal foil or the like. This metal foil typically has much greater thickness than the combined thickness of all the thin film layers above it. In one example, the substrate has a thickness of 100 microns or more. Some embodiments may have substrates with thicknesses greater than 200 microns. More details of some cell configurations can be found in U.S. patent application Ser. No. ______ (Attorney Docket No NSL-043) filed ______

Referring back to FIG. 11, the first device module 301 may be attached to the carrier substrate 303 such that the back plane 308 makes electrical contact with the thin conducting layer 328 while leaving a portion of the thin conducting layer 328 exposed. Electrical contact may then be made between the exposed portion of the thin conducting layer 328 and the exposed portion of the bottom electrode 314 of the second device module 311. For example, a bump of conductive material 329 (e.g., more conductive adhesive) may be placed on the thin conducting layer 328 at a location aligned with the exposed portion of the bottom electrode 314. The bump of conductive material 329 is sufficiently tall as to make contact with the exposed portion of the bottom electrode 314 when the second device module 311 is attached to the carrier substrate. The dimensions of the notches 317, 319 may be chosen so that there is essentially no possibility that the thin conducting layer 328 will make undesired contact with the back plane 318 of the second device module 311. For example, the edge of the bottom electrode 314 may be cut back with respect to the insulating layer 316 by an amount of cutback CB₁ of about 400 microns. The back plane 318 may be cut back with respect to the insulating layer 316 by an amount CB₂ that is significantly larger than CB₁.

The device layers 302, 312 are preferably of a type that can be manufactured on a large scale, e.g., in a roll-to-roll processing system. There are a large number of different types of device architectures that may be used in the device layers 302, 312. By way of example, and without loss of generality, the inset in FIG. 11 shows the structure of a CIGS active layer 307 and associated layers in the device layer 302. By way of example, the active layer 307 may include an absorber layer 330 based on materials containing elements of groups IB, IIIA and VIA. Preferably, the absorber layer 330 includes copper (Cu) as the group IB, Gallium (Ga) and/or Indium (In) and/or Aluminum as group IIIA elements and Selenium (Se) and/or Sulfur (S) as group VIA elements. Examples of such materials (sometimes referred to as CIGS materials) are described in U.S. Pat. No. 6,268,014, issued to Eberspacher et al on Jul. 31, 2001, and US Patent Application Publication No. US 2004-0219730 A1 to Bulent Basol, published Nov. 4, 2004, both of which are incorporated herein by reference. A window layer 332 is typically used as a junction partner between the absorber layer 330 and the transparent conducting layer 309. By way of example, the window layer 332 may include cadmium sulfide (CdS), zinc sulfide (ZnS), or zinc selenide (ZnSe) or some combination of two or more of these. Layers of these materials may be deposited, e.g., by chemical bath deposition or chemical surface deposition, to a thickness of about 50 nm to about 100 nm. A layer 334 of a metal different from the bottom electrode may be disposed between the bottom electrode 304 and the absorber layer 330 to inhibit diffusion of metal from the bottom electrode 304. For example, if the bottom electrode 304 is made of aluminum, the layer 334 may be a layer of molybdenum. This may help carry electrical charge and provide certain protective qualities. In addition, another layer 335 of material similar to that of layer 103 may also be applied between the layer 334 and the aluminum layer 304. The material may be the same as that of layer 103 or it may be another material selected from the set of material listed for layer 103. Optionally, another layer 337 also be applied to the other side of layer 304. The material may be the same as that of layer 335 or it may be another material selected from the set of material listed for layer 103. Protective layers similar to layers 335 and/or 337 may be applied around the foil on any of the embodiments described herein.

Some embodiments can use diodes selected from one or more the following:

| | | | | |
|---|---|---|---|---|
| Current (A) | >10 | 10 | 10 | 2 |
| Thickness (um) | 150 | 1000 | 250 | 500 |

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, it should be understood that they are not limited to filling empty or partially filled vias. They can be used for high accuracy deposition for other purposes and on other target materials. Some alternative embodiments may use a conveyor belt with gaps for backlighting the vias. Optionally, translucent rollers may be used. Although they generally do not work well for through holes, they maybe suitable for other types of filling or hole creation. At 10 microns, everything either absorbs or reflects. If one has a glass roller, the deposition head or nozzle will mark it up constantly. With a metal roller, reflection of deposition head or nozzle will mess up the hole and reflection will come up and fill in some other place. However, some embodiments may control such reflections. Optionally, a material dispense mechanism can also be employed on a stationary substrate with a moving dispense head.

Furthermore, those of skill in the art will recognize that any of the embodiments of the present invention can be applied to almost any type of solar cell material and/or architecture. For example, the absorber layer in solar cell 10 may be an absorber layer comprised of silicon, amorphous silicon, copper-indium-gallium-selenium (for CIGS solar cells), CdSe, CdTe, Cu(In,Ga)(S,Se)₂, Cu(In,Ga,Al)(S,Se,Te)₂, (Cu,Au,Ag)(In,Ga,Al)(S,Se,Te)₂, Cu—In, In—Ga, Cu—Ga, Cu—In—Ga, Cu—In—Ga—S, Cu—In—Ga—Se, other absorber materials, II-VI materials, IB-VI materials, CuZnTe, CuTe, ZnTe, IB-IIB-IVA-VIA absorbers, or other alloys, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a size range of about 1 nm to about 200 nm should be interpreted to include not only the explicitly recited limits of about 1 nm and about 200 nm, but also to include individual sizes such as 2 nm, 3 nm, 4 nm, and sub-ranges such as 10 nm to 50 nm, 20 nm to 100 nm, etc. . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. patent application Ser. Nos. 11/207,157 filed Aug. 16, 2005 and 12/064,031 filed Aug. 16, 2006 are fully incorporated herein by reference for all purposes. U.S. Provisional Application Ser. No. 61173,570 filed Apr. 28, 2009, is fully incorporated herein by reference for all purposes.

Various aspects of the invention of the invention relating to the above are enumerated in the following paragraphs:

Aspect 1. A thin film solar cell with avalanche breakdown protection.

Aspect 2. The device of Aspect 1 comprising:

a non-elongated, non-silicon thin-film solar cell using an electrically conductive foil substrate wherein the foil substrate carries current when the cell is forward biased, the substrate having a ratio of width to length greater than about 0.5 along an axis of current flow, and when exposed to light at AM 1.5 G, the solar cell has an Impp greater than about 2 amps;

wherein the solar cell exhibits avalanche breakdown down at one or more locations in the cell;

an avalanche breakdown protection unit to prevent the avalanche breakdown at the one or more locations by directing current through the protection unit.

Aspect 3. The device of Aspect 1 wherein the conductive substrate creates the avalanche breakdown due to the much larger current that can be delivered to any one location in the cell.

Aspect 4. The device of Aspect 1 wherein the non-elongated solar cell is not susceptible to shading and the diode is not activated when the cell is shaded.

Aspect 5. The device of Aspect 1 wherein the non-elongated solar cell is not susceptible to shading and the diode is not activated when the cell is shaded.

Aspect 6. The device of Aspect 1 wherein the non-elongated solar cell is not monolithically integrated with another cell.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A thin film solar cell with avalanche breakdown protection.

2. The device of claim 1 comprising:
a non-elongated, non-silicon thin-film solar cell using an electrically conductive foil substrate wherein the foil substrate carries current when the cell is forward biased, the substrate having a ratio of width to length greater than about 0.5 along an axis of current flow, and when exposed to light at AM 1.5 G, the solar cell has an Impp greater than about 2 amps;
wherein the solar cell exhibits avalanche breakdown down at one or more locations in the cell;
an avalanche breakdown protection unit to prevent the avalanche breakdown at the one or more locations by directing current through the protection unit.

3. The device of claim 1 comprising:
wherein the conductive substrate creates the avalanche breakdown due to the much larger current that can be delivered to any one location in the cell.

4. The device of claim 1 comprising:
wherein the non-elongated solar cell is not susceptible to shading and the diode is not activated when the cell is shaded.

5. The device of claim 1 comprising:
wherein the non-elongated solar cell is not monolithically integrated with another cell.
